(19) United States
(12) Patent Application Publication
(10) Pub. No.: US 2024/0107835 A1
(43) Pub. Date: Mar. 28, 2024

(54) DISPLAY DEVICE AND METHOD OF MANUFACTURING THE SAME

(71) Applicant: SAMSUNG DISPLAY CO., LTD., YONGIN-SI (KR)

(72) Inventors: BYUNGHOON KIM, Yongin-si (KR); Misun Kim, Yongin-si (KR); Taeoh Kim, Yongin-si (KR)

(21) Appl. No.: 18/372,857

(22) Filed: Sep. 26, 2023

(30) Foreign Application Priority Data
Sep. 27, 2022 (KR) 10-2022-0122148

(51) Int. Cl. H10K 59/131; H10K 59/12

(52) U.S. Cl. CPC H10K 59/131; H10K 59/1201

(57) ABSTRACT

A display device includes a lower inorganic barrier layer. Pad electrodes are disposed on the lower inorganic barrier layer and penetrate the lower inorganic barrier layer. The pad electrodes are spaced apart from each other. An upper inorganic barrier layer is disposed on the lower inorganic barrier layer and covers the pad electrodes. An upper organic base layer is disposed on the upper inorganic barrier layer. A circuit layer is disposed on the upper organic base layer. A light emitting element layer is disposed on the circuit layer. A lower organic base layer is disposed under the lower inorganic barrier layer. The lower organic base layer includes a first portion defining contact openings respectively exposing the pad electrodes penetrating the lower inorganic barrier layer. A second portion is disposed under the first portion. The second portion defines a pad opening exposing the contact openings.

### CROSS-REFERENCE TO RELATED APPLICATION

This application claims priority under 35 U.S.C. § 119 to Korean Patent Application No. 10-2022-0122148, filed on Sep. 27, 2022 in the Korean Intellectual Property Office, the disclosure of which is incorporated by reference in its entirety herein.

### 1. TECHNICAL FIELD

Embodiments of the present disclosure relate generally to a display device and a method of manufacturing the display device.

### 2. DISCUSSION OF RELATED ART

A display device may include a pixel emitting light for displaying images. The pixel emitting light may be disposed in a display area.

The display device may include a driving part providing a driving signal to the pixel. The driving part is electrically connected to the pixel to provide the driving signal to the pixel. For example, the driving part may be electrically connected to a pad electrode that is electrically connected to the pixel.

To electrically connect the driving part to the pad electrode, an opening exposing the pad electrode may be formed in a base layer disposed under the pad electrode by a laser. In this case, components, such as organic layers, disposed on the pad electrode may be damaged by the laser, and accordingly, the display quality of the display device may decrease.

### SUMMARY

Embodiments of the present disclosure provide a display device with increased display quality.

According to an embodiment of the present disclosure, a display device includes a lower inorganic barrier layer. Pad electrodes are disposed on the lower inorganic barrier layer and penetrate the lower inorganic barrier layer. The pad electrodes are spaced apart from each other. An upper inorganic barrier layer is disposed on the lower inorganic barrier layer and covers the pad electrodes. An upper organic base layer is disposed on the upper inorganic barrier layer. A circuit layer is disposed on the upper organic base layer. A light emitting element layer is disposed on the circuit layer. A lower organic base layer is disposed under the lower inorganic barrier layer. The lower organic base layer includes a first portion defining contact openings respectively exposing the pad electrodes penetrating the lower inorganic barrier layer. A second portion is disposed under the first portion. The second portion defines a pad opening exposing the contact openings.

In an embodiment, the contact openings may be disposed in a pad opening area comprising an area surrounded by an outer edge of the pad opening in a plan view.

In an embodiment, the pad electrodes may be disposed in the pad opening area in the plan view.

In an embodiment, the contact openings may be spaced apart from each other.

In an embodiment, the first portion of the lower organic base layer may include protrusion portions disposed between adjacent contact openings of the contact openings.

In an embodiment, a thickness of each of the protrusion portions may be in a range of about 0.1 micrometer to about 2 micrometer in a cross sectional view.

In an embodiment, a thickness of each of the contact openings may be less than a thickness of the pad opening in a cross sectional view.

In an embodiment, the light emitting element layer may include light emitting elements. The pad opening may be disposed in a display area that has the light emitting elements disposed therein in a plan view.

In an embodiment, each of the pad electrodes may include a first electrode layer disposed on the lower inorganic barrier layer, and a second electrode layer disposed under the first electrode layer. An electric conductivity of the second electrode layer is less than an electric conductivity of the first electrode layer.

In an embodiment, the display device may further include a driving part disposed under the lower organic base layer. The driving part is electrically connected to each of the pad electrodes exposed by the contact openings. The driving part is electrically connected to the second electrode layer.

According to an embodiment of the present disclosure, a method of manufacturing a display device may include forming a preliminary lower organic base layer. A lower inorganic barrier layer is formed on the preliminary lower organic base layer. Pad electrodes are formed that penetrate the lower inorganic barrier layer. An upper inorganic barrier layer is formed on the lower inorganic barrier layer to cover the pad electrodes. An upper organic base layer is formed on the upper inorganic barrier layer. A lower organic base layer is formed by irradiating a laser beam in a direction toward a lower surface of the preliminary lower organic base layer. The lower organic base layer includes a first portion defining contact openings exposing the pad electrodes penetrating the lower inorganic barrier layer. A second portion is disposed under the first portion. The second portion defines a pad opening exposing the contact openings.

In an embodiment, the forming of the lower organic base layer may include forming the second portion defining the pad opening and a remaining portion disposed on the second portion by irradiating a first laser beam to remove a portion of the preliminary lower organic base layer, and forming the first portion defining the contact openings by irradiating a second laser beam to remove a portion of the remaining portion exposed by the pad opening.

In an embodiment, a transmittance of the first laser beam with respect to the remaining portion may be about 15% or less.

In an embodiment, the contact openings may be spaced apart from each other,

In an embodiment, a light emitting element layer is formed above the upper organic base layer. The light emitting element layer includes light emitting elements. The pad opening may be disposed in a display area having the light emitting elements disposed therein.

In an embodiment, the first portion of the lower organic base layer may include protrusion portions disposed between adjacent contact openings of the contact openings.

In an embodiment, a thickness of each of the protrusion portions is in a range of about 0.1 micrometer to about 2 micrometer in a cross sectional view.

In an embodiment, a thickness of each of the contact openings may be less than a thickness of the pad opening in a cross sectional view.

In an embodiment, each of the pad electrodes may include a first electrode layer disposed on the lower inorganic barrier layer, and a second electrode layer disposed under the first electrode layer. An electric conductivity of the second electrode layer is less than an electric conductivity of the first electrode layer.

In an embodiment, a driving part is formed under the lower base layer. The driving part is electrically connected to each of the pad electrodes exposed by the contact openings. The driving part is electrically connected to the second electrode layer.

In the display device according to embodiments, the contact openings may expose the pad electrodes penetrating the lower inorganic barrier layer. In this case, the contact openings may correspond to the pad electrodes in one-to-one correspondence, and may overlap the pad electrodes in a plan view. Accordingly, in a laser process of forming the contact openings, the pad electrodes may function as a barrier of the laser, and the upper organic base layer disposed on the pad electrodes may not be damaged by the laser.

### BRIEF DESCRIPTION OF THE DRAWINGS

Illustrative, non-limiting embodiments of the present disclosure will be more clearly understood from the following detailed description in conjunction with the accompanying drawings.

FIG. 1 is a diagram illustrating a display device according to an embodiment of the present disclosure.

FIG. 2 is a plan view illustrating a first sub display panel included in the display device of FIG. 1 according to an embodiment of the present disclosure.

FIG. 3 is a cross-sectional view taken along a line I-I′ of FIG. 2 according to an embodiment of the present disclosure.

FIG. 4 is an enlarged plan view of area B of FIG. 2 according to an embodiment of the present disclosure.

FIG. 5 is a cross-sectional view taken along a line II-II′ of FIG. 4 according to an embodiment of the present disclosure.

FIG. 6 is a cross-sectional view taken along a line III-III′ of FIG. 4 according to an embodiment of the present disclosure.

FIG. 7, FIG. 8, and FIG. 9 are cross-sectional views illustrating a method of manufacturing the display device of FIG. 1 according to embodiments of the present disclosure.

### DETAILED DESCRIPTION OF EMBODIMENTS

Hereinafter, embodiments of the present disclosure will be explained in detail with reference to the accompanying drawings. The same reference numerals are used for the same components in the drawings, and redundant descriptions of the same components may be omitted for economy of description.

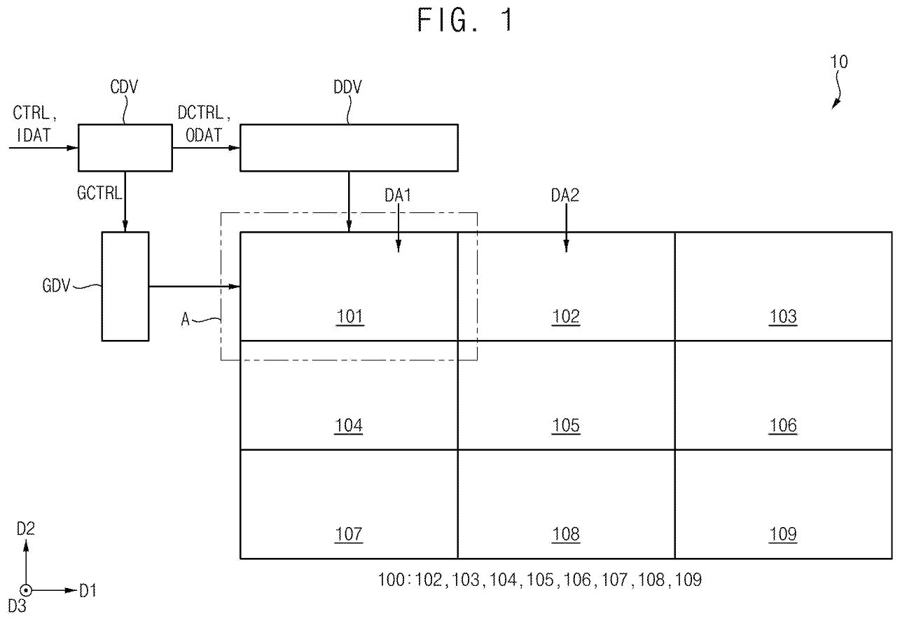

FIG. 1 is a diagram illustrating a display device according to an embodiment of the present disclosure.

Referring to FIG. 1, a display device 10 may include a display panel 100 and a panel driving part.

The display panel 100 may include a plurality of sub display panels. For example, as shown in FIG. 1, in an embodiment the display panel 100 may include first to ninth sub display panels 101, 102, 103, 104, 105, 106, 107, 108, and 109 arranged in 3×3 matrix shape. Each of the first to ninth sub display panels 101, 102, 103, 104, 105, 106, 107, 108, and 109 may display an image. For example, an area where an image is displayed in the first sub display panel 101 may be defined as a first display area DA1, and an area where an image is displayed in the second sub display panel 102 may be defined as a second display area DA2. In this embodiment, the user of the display device 10 may view a combined image of images displayed on the first to ninth sub display panels 101, 102, 103, 104, 105, 106, 107, 108, and 109. However, embodiments of the present disclosure are not necessarily limited thereto. For example, in some embodiments, the plurality of sub display panels may be arranged in various other combinations, such as 1×2, 1×3, 1×4, 2×1, 3×1, 4×1, 3×3, and 4×4. Additionally, in some embodiments, at least some of the sub display panels may display separate images that are not combined with images generated by other sub display panels.

The panel driving part may include a plurality of sub panel driving parts for driving the plurality of sub display panels. For example, a first sub panel driving part for driving the first sub display panel 101 may include a first driving control part (also referred to as a data driving part) CDV, a first gate driving part GDV, and a first data driving part DDV. In an embodiment, the second to ninth sub display panels 102, 103, 104, 105, 106, 107, 108, and 109 may be respectively driven by second to ninth sub panel driving parts.

Each of the first to ninth sub display panels 101, 102, 103, 104, 105, 106, 107, 108, and 109 may have a substantially same structure as each other. Accordingly, hereinafter, the first sub display panel 101 will be described as a reference and a repeated description may not be included for economy of description.

The first driving control part CDV may generate a gate control signal GCTRL, a data control signal DCTRL, and an output image data ODAT based on an input image data DAT and an input control signal CTRL provided from an external device. In an embodiment, the input image data IDAT may be a RGB data including a red image data, blue image data, and a green image data. The input control signal CTRL, may include a master clock signal, an input data enable signal, a vertical sync signal, a horizontal sync signal, etc. However, embodiments of the present disclosure are not necessarily limited thereto.

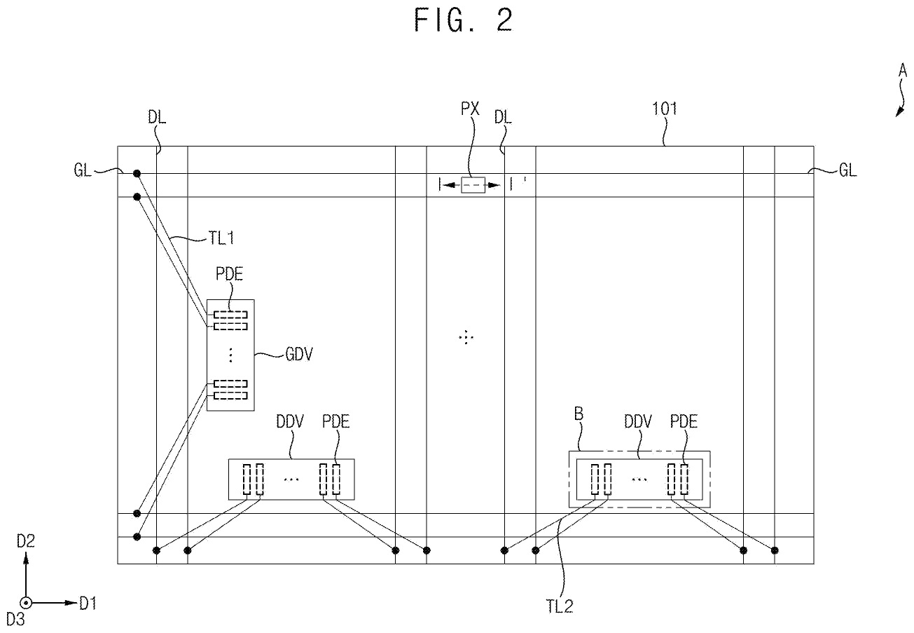

The first gate driving part GDV may generate a plurality of gate signals based on the gate control signal GCTRL, provided from the first driving control part CDV. For example, the gate control signal GCTRL may include a vertical initiation signal and a gate clock signal. The first gate driving part GDV may sequentially output the gate signals to gate lines (refer to GL in FIG. 2) of the first sub display panel 101.

The first data driving part DDV may generate a plurality of data signals based on the data control signal DCTRL and the output image data ODAT provided from the first driving control part CDV. For example, the data control signal DCTRL may include an output data enable signal, a horizontal initiation signal, and a load signal, etc. The first data driving part DDV may output the data signals to data lines (refer to DL of FIG. 2) of the first sub display panel 101.

FIG. 2 is a plan view illustrating a first sub display panel included in the display device of FIG. 1 according to an embodiment of the present disclosure.

Referring to FIG. 1 and FIG. 2, FIG. 2 is an enlarged plan view of area A of FIG. 1, and FIG. 2 is a plan view illustrating a back surface of the first sub display panel 101.

The first sub display panel 101 may include pixels PX, gate lines GL, data lines DL, pad electrodes PDE, and transmission lines.

The pixels PX may be generally disposed in the first sub display panel 101, and may be electrically connected to the gate lines GL and the data lines DL. Each of the pixels PX may emit light, and accordingly, the first sub display panel 101 may display an image. In this embodiment, an area in which the pixels PX are disposed may be defined as the first display area DA1.

The gate lines GL and the data lines DL may cross each other. For example, each of the gate lines GL may extend in a first direction D1, and the gate lines GL may be arranged in a second direction D2 crossing the first direction D1. For example, in an embodiment, the first direction D1 and the second direction D2 may be perpendicular to each other. However, embodiments of the present disclosure are not necessarily limited thereto. Each of the data lines DL may extend in the second direction D2, and the data lines DL may be arranged in the first direction D1. In an embodiment, the first direction D1 may be perpendicular to the second direction D2. However, embodiments of the present disclosure are not necessarily limited thereto.

In an embodiment the first gate driving part GDV and the first data driving part DDV may be an integrated circuit (IC). For example, as shown in FIG. 2, the first gate driving part GDV and the first data driving part DDV may be disposed on the back surface of the first sub display panel 101. For example, the first gate driving part GDV and the first data driving part DDV may be disposed to overlap the first display area DA1. In this embodiment, the first gate driving part GM and the first data driving part DDV may include an IC chip, a substrate including an IC chip, a film including an IC chip, etc.

In an embodiment, the first gate driving part GDV and/or the first data driving part DDV may be provided in plural, and may be disposed on the back surface of the first sub display panel 101. For example, as shown in FIG. 2, in an embodiment one first gate driving part GDV and two data driving parts DDV ray be disposed on the hack surface of the first sub display panel 101. However, embodiments of the present disclosure are not necessarily limited thereto. For example, in some embodiments the first gate driving part GDV and the first data driving part DDV may be divided into one or three or more according to the number of the gate lines GL and the data lines DL.

The transmission lines may include first transmission lines TL1 and second transmission lines TL2. In an embodiment, each of the first transmission lines TL1 may transmit the gate signals provided from the first gate driving part GDV to the gate lines GL. Each of the second transmission lines TL2 may transmit the data signals provided from the first data driving part DDV to the data lines DL. In an embodiment, the first transmission liens TL1 may correspond to the gate lines GL in one-to-one correspondence, and the second transmission lines TL2 may correspond to the data lines DL in one-to-one correspondence. However, embodiments of the present disclosure are not necessarily limited thereto.

The pad electrodes PDE may electrically connect the transmission lines to the first gate driving part GDV and the first data driving part DDV. In an embodiment, the pad electrodes PDE may correspond to the transmission lines in one-to-one correspondence.

The pad electrodes PDE may be electrically connected to the first gate driving part GDV and the first data driving part DDV. Accordingly, the gate signals provided from the first gate driving part GDV may be transmitted to the gate lines GL through the pad electrodes PDE and the first transmission lines TL1. In addition, the data signals provided from the first data driving part DDV may be transmitted to the data lines DL through the pad electrodes PDE and the second transmission lines TL2.

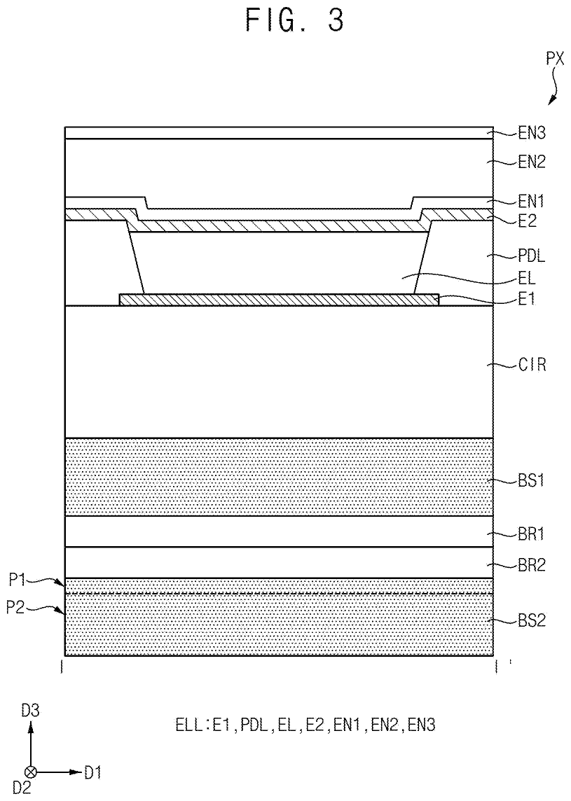

FIG. 3 is a cross-sectional view taken along a line I-I′ of FIG. 2 according to an embodiment of the present disclosure. FIG. 3 is a cross-sectional view illustrating one of the pixels PX.

Referring to FIG. 3 and in conjunction with FIG. 2, the first sub display panel 101 may include a lower organic base layer BS2, a lower inorganic barrier layer BR2, an upper inorganic barrier layer BR1, an upper organic base layer BS1, a circuit layer CIR, and a light emitting element layer ELL that includes light emitting elements.

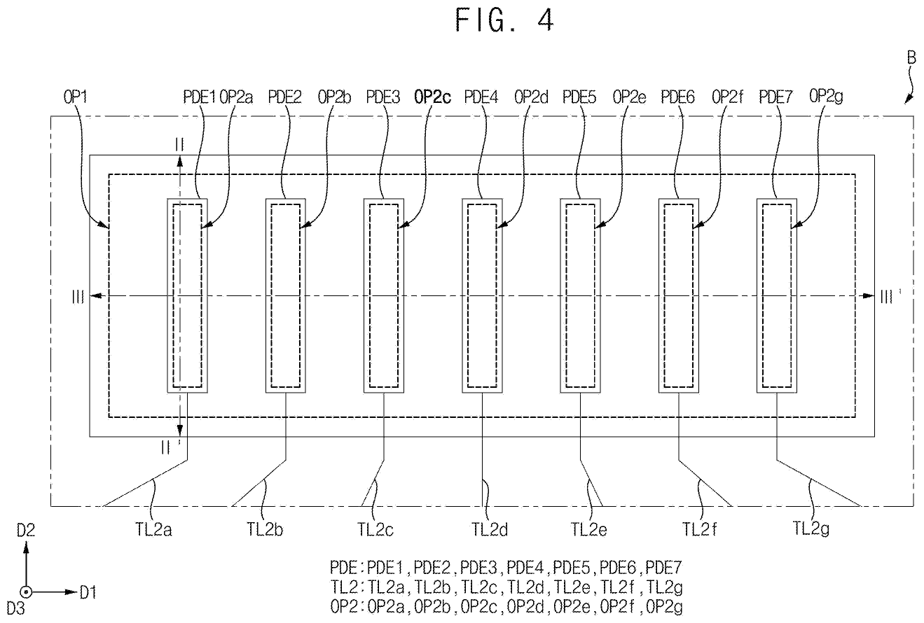

The lower organic base layer BS2 may include an organic insulation material. The lower organic base layer BS2 may include a first portion P1 and a second portion P2 disposed under the first portion P1 (e.g., in a third direction D3 that is a thickness direction of the lower organic base layer BS2 and crosses the first and second directions D1, D2). The lower organic base layer BS2 may define an opening exposing the pad electrodes PDE, and the first gate driving part GDV and the first data driving part DDV may be electrically connected to the pad electrodes PDE through the opening. The opening will be described later with reference to FIG. 4 to FIG. 6.

The lower inorganic barrier layer BR2 may be disposed on (e.g., disposed directly thereon in the third direction D3) the lower organic base layer BS2. The upper inorganic barrier layer BR1 may be disposed on (e.g., disposed directly thereon in the third direction D3) the lower inorganic barrier layer BR2. Each of the lower inorganic barrier layer BR2 and the upper inorganic barrier layer BR1 may include an inorganic insulation material. The pad electrodes PDE may be disposed between the lower inorganic barrier layer BR2 and the upper inorganic barrier layer BR1. For example, the pad electrodes PDE may be disposed on the lower inorganic barrier layer BR2 and may penetrate the lower inorganic barrier layer BR2. The upper inorganic barrier layer BR1 tray cover the pad electrodes PDE. The pad electrodes PDE will be described later with reference to FIG. 4 to FIG. 6.

The upper organic base layer BS1 may be disposed on (e.g., disposed directly thereon in the third direction D3) the upper inorganic barrier layer BR1. The upper organic base layer BS1 may include an organic insulation material.

The circuit layer CIR may be disposed on e.g., disposed directly thereon in the third direction D3) the upper organic base layer BS1. The circuit layer CIR may include conductive layers and insulation layers. In this embodiment, the conductive layers included in the circuit layer CIR may include the gate lines GL and the data lines DL described with reference to FIG. 2. In addition, the circuit layer CIR may include at least one transistor. For example, the circuit layer CIR may include a driving transistor.

The light emitting element layer ELL which includes light emitting elements may be disposed on (e.g., disposed directly thereon in the third direction D3) the circuit layer CIR. In an embodiment, the light emitting element layer ELL may include a first electrode E1, a pixel defining layer PDL, a light emitting layer EL, a second electrode E2, a first inorganic encapsulation layer EN1, an organic encapsulation layer EN2, and a second inorganic encapsulation layer EN3.

The first electrode E1 may be disposed on (e.g., disposed directly thereon in the third direction D3) the circuit layer CIR. The first electrode E1 may include a conductive material. The first electrode E1 may be electrically connected to the driving transistor included in the circuit layer CIR, and accordingly, a driving current generated by the driving transistor may be provided to the first electrode E1. In an embodiment, the first electrode E1 may be referred to as an anode electrode.

The pixel defining layer PDL may be disposed on (e.g., disposed directly thereon) the circuit layer CIR, and the first electrode E1. For example, in an embodiment, the pixel defining layer PDL may cover lateral sides of the first electrode E1 and may expose a central portion of the first electrode E1 to form a pixel opening. The pixel defining layer PDL may define a pixel electrode exposing the first electrode E1. The pixel defining layer PDL may include an organic insulation material.

The light emitting layer EL may be disposed on (e disposed directly thereon in the third direction D3) the first electrode E1 in the pixel opening. The light emitting layer EL may include a material emitting light. For example, the light emitting layer EL may include an organic light emitting material.

The second electrode E2 may be disposed on the light emitting layer EL (e.g., in the third direction D3). In an embodiment, the second electrode E2 may cover the light emitting layer EL and the pixel defining layer PDL. The second electrode E2 may include a conductive material. In an embodiment, the second electrode E2 may be referred to as a cathode electrode.

The first inorganic encapsulation layer EN1, the organic encapsulation layer EN2, and the second inorganic encapsulation layer EN3 may be sequentially disposed on the second electrode E2 (e.g., in the third direction D3). In this embodiment, the first inorganic encapsulation layer EN1, the organic encapsulation layer EN2, and the second inorganic encapsulation layer EN3 may define an encapsulation layer. The encapsulation layer may protect the second electrode E2, the light emitting layer EL, and the first electrode E1 from moisture and impurities.

The first inorganic encapsulation layer EN1 may be disposed on the second electrode E2 (e.g., in the third direction D3), and may cover the second electrode E2. The first inorganic encapsulation layer EN1 may include an inorganic insulation material.

The organic encapsulation layer EN2 may be disposed on (e.g., disposed directly thereon in the third direction D3) the first inorganic encapsulation layer EN1, and may cover the first inorganic encapsulation layer EN1. The organic encapsulation layer EN2 may include an organic insulation material.

The second inorganic encapsulation layer EN3 may be disposed on e.g., disposed directly thereon in the third direction D3) the organic encapsulation layer EN2, and may cover the organic encapsulation layer EN2. The second inorganic encapsulation layer EN3 may include an inorganic insulation material.

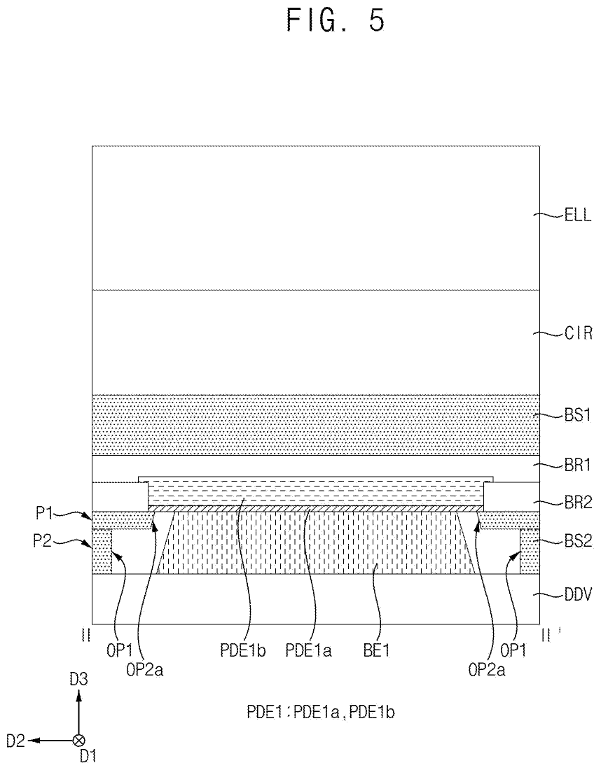

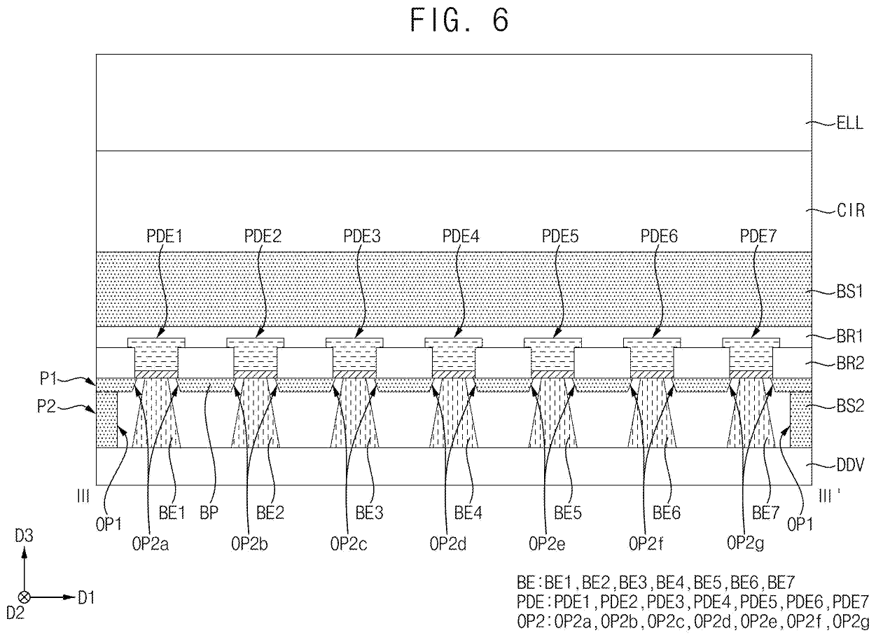

FIG. 4 is an enlarged plan view of area B of FIG. 2 according to an embodiment of the present disclosure. FIG. 5 is a cross-sectional view taken along a line II-II′ of FIG. 4 according to an embodiment of the present disclosure. FIG. 6 is a cross-sectional view taken along a line III-III′ of FIG. 4 according to an embodiment of the present disclosure.

Referring to FIG. 4, FIG. 5, and FIG. 6 and in conjunction with FIG. 2, in an embodiment, the pad electrodes PDE may include first to seventh pad electrodes PDE1, PDE2, PDE3, PDE4, PDE5, PDE6, and PDE7, and the second transmission lines TL2 may include first to seventh transmission lines TL2a, TL2b, TL2c, TL2d, TL2e, TL2e, TL2f, and TL2g. However, embodiments of the present disclosure are not necessarily limited thereto. For example, the number of each of the pad electrodes PDE and the second transmission lines TL2 may be greater than 8 or less than 7 in some embodiments.

The first to seventh pad electrodes PDE1, PDE2, PDE3, PDE4, PDE5, PDE6, and PDE7 may be arranged in the first direction D1 and may be spaced apart from each other. The first to seventh transmission lines TL2a, TL2b, TL2c, TL2d, TL2e, TL2f, and TL2g may connected to the first to seventh pad electrodes PDE1, PDE2, PDE3, PDE4, PDE5, PDE6, and PDE7 in one-to-one correspondence. The first to seventh transmission lines TL2a, TL2b, TL2c, TL2d, TL2e, TL2f, and TL2g may be electrically connected to the first to seventh pad electrodes PDE1, PDE2, PDE3, PDE4, PDE5, PDE6, and PDE7, and at the same time, may be electrically connected to the data lines DL.

The data driving part DDV may be disposed under the lower organic base layer BS2 (e.g., in the third direction D3). In this embodiment, for electrically connecting the data driving part DDV to the pad electrodes PDE, a pad opening OP1 may be defined in the second portion P2 of the lower organic base layer BS2, and contact openings OP2 may be defined in the first portion P1 of the lower organic base layer BS2. For example, a portion of the lower organic base layer BS2 disposed between the data driving part DDV and the pad electrodes PDE (e.g., in the third direction D3) may be removed.

The pad opening OP1 may expose the contact openings OP2. More specifically, as shown in FIG. 4, the contact openings OP2 may be disposed in a pad opening area including or defined as an area surrounded by an outer edge of the pad opening OP1 in a plan view. In this embodiment, the pad electrodes PDE positioned to overlap the contact openings OP2 (e.g., in the third direction D3) may be disposed in the pad opening area.

The pad opening OP1 may overlap the first display area DA1. For example, the light emitting element layer ELL may be disposed on the pad opening OP1 (e.g., in the third direction D3), and accordingly, an image may be displayed in an area in which the pad opening OP1 is defined.

In an embodiment, the contact openings OP2 may include first to seventh contact openings OP2a, OP2b, OP2c, OP2d, OP2e, OP2f, and OP2g. The first to seventh contact openings OP2a, OP2b, OP2c, OP2d, OP2e, OP2f, and OP2g may be spaced apart from each other (e.g., in the first direction D1), and may be disposed to overlap the first to seventh pad electrodes PDE1, PDE2, PDE3, PDE4, PDE5, PDE6, and PDE7, respectively (e.g., in the third direction D3). For example, the first contact opening OP2a may be disposed to overlap the first pad electrode PDE1 (e.g., in the third direction D3), and accordingly, the first pad electrode PDE1 may be exposed by the pad opening OP1 and the first contact opening OP2a. In an embodiment, the second contact opening OP2b may be disposed to be spaced apart from the first contact opening OP2a (e.g., in the first direction D1) and to overlap the second pad electrode PDE2 (e.g., in the third direction D3). Accordingly, the second pad electrode PDE2 may be exposed by the pad opening OP1 and the second contact opening OP2b.

Although FIG. 4, FIG. 5 and FIG. 6 shows an example which the contact openings OP2 expose a portion of the corresponding pad electrodes PDE, embodiments of the present disclosure are not necessarily limited thereto. For example, in an embodiment, the contact openings OP2 may completely expose the corresponding pad electrodes PDE. For example, an area surrounded by an outer edge of the first contact opening OP2a may completely overlap an area surrounded by an outer edge of the first pad electrode PDE1.

In an embodiment, a thickness of each of the contact openings OP2 in the third direction D3 (e.g., in a cross-sectional view) may be less than a thickness of the pad opening OP1 in the third direction D3.

The first portion P1 of the lower organic base layer BS2 may include a protrusion portion disposed between two adjacent contact openings OP2 among the contact openings OP2. For example, as shown in FIG. 6, the protrusion portion BP may be disposed between the first contact opening OP2a and the second contact opening OP2b (e.g., in the first direction D1). In an embodiment, a thickness of each of the protrusion portions BP (e.g., in a cross-sectional view, such as in the third direction D3) may be in a range of about 0.1 micrometer to about 2 micrometer.

In an embodiment, each of the pad electrodes PDE may include a first electrode layer disposed on the lower inorganic barrier layer BR2 and a second electrode layer disposed under the first electrode layer in the third direction D3). For example, each of the pad electrodes PDE may have a multi-layer structure including the first electrode layer and the second electrode layer. However, embodiments of the present disclosure are not necessarily limited thereto and the pad electrodes PDE may have three or more electrode layers in some embodiments. For example, as shown in FIG. 5, the first pad electrode PDE1 may include a second pad electrode layer PDE1a and a first pad electrode layer PDE1b disposed on (e.g., disposed directly thereon in the third direction D3) the second pad electrode layer PDE1a.

In this embodiment, the second electrode layer may be exposed by the opening defined by the lower organic base layer BS2. For example, a portion of a lower surface of the second pad electrode layer PDE1a may be exposed by the first contact opening OP2a and the pad opening OP1.

Since the second electrode layer is exposed by the opening, the second electrode layer may be vulnerable to damage caused by moisture and impurities. To prevent this, the second electrode layer may include a conductive material having excellent corrosion resistance. For example, in an embodiment the second electrode layer, such as the second pad electrode layer PDE1a may include titanium. However, embodiments of the present disclosure are not necessarily limited thereto.

In contrast, the first electrode layer, such as the first pad electrode layer PDE1b, may not be exposed by the opening. For example, the first electrode layer may be covered by the lower inorganic barrier layer BR2 and the upper inorganic barrier layer BR1. Accordingly, the first electrode layer may include a conductive material having a greater electrical conductivity as compared to the second electrode layer even though corrosion resistance of the conductive material is relatively low. For example, in an embodiment the first electrode layer may include copper. In this embodiment, a conductivity of the first electrode layer may be greater than a conductivity of the second electrode layer. However, embodiments of the present disclosure are not necessarily limited thereto and the first electrode layer may include various conductive materials.

The first data driving part DDV may be electrically connected to the pad electrodes PDE. For example, connection elements BE may be disposed between the first data driving part DDV and the pad electrodes PDE (e.g., in the third direction D3), and the connection elements BE may electrically connect the first data driving part DDV to the pad electrodes PDE.

The shape and type of the connection element BE are not necessarily limited to those shown in embodiments of FIGS. 5-6, and various elements capable of electrically connecting the first data driving part DDV to the pad electrodes PDE may be used as the connection elements BE. For example, in some embodiments the connection elements BE may be implemented with a conductive film, a conductive ball, or resin including the conductive ball.

In an embodiment, the connection elements BE may include first to seventh conductive elements BE1, BE2, BE3, BE4, BE5, BE6, and BE7. The first to seventh conductive elements BE1, BE2, BE3, BE4, BE5, BE6, and BE7 may be connected to the first to seventh pad electrodes PDE1, PDE2, PDE4, PDE6, and PDE7 in one-to-one correspondence, and may electrically contact the first to seventh pad electrodes PDE1, PDE2, PDE3, PDE4, PDE5, PDE6, and PDE7. For example, in an embodiment the first conductive element BE1 may physically and electrically contact a lower surface of the first pad electrode layer PDE1a through the pad opening OP1 and the first contact opening OP2a. The first to seventh conductive elements BE1, BE2, BE3, BE4, BE5, BE6, and BE7 may physically and electrically contact the first data driving part DDV.

In FIG. 4, FIG. 5, and FIG. 6, the first data driving part DDV and the pad electrodes PDE electrically connected to the first data driving part DDV have been described. In this embodiment, the structure of the first gate driving part GDV and the pad electrodes PDE electrically connected to the first gate driving part GDV may be substantially same or similar to the structure of the first data driving part DDV and the pad electrodes PDE electrically connected to the first data driving part DDV.

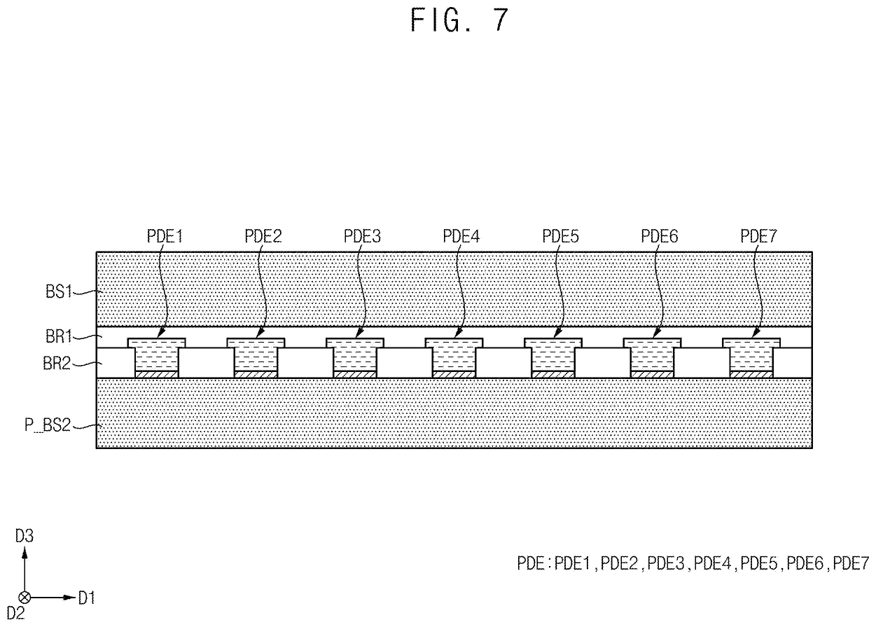

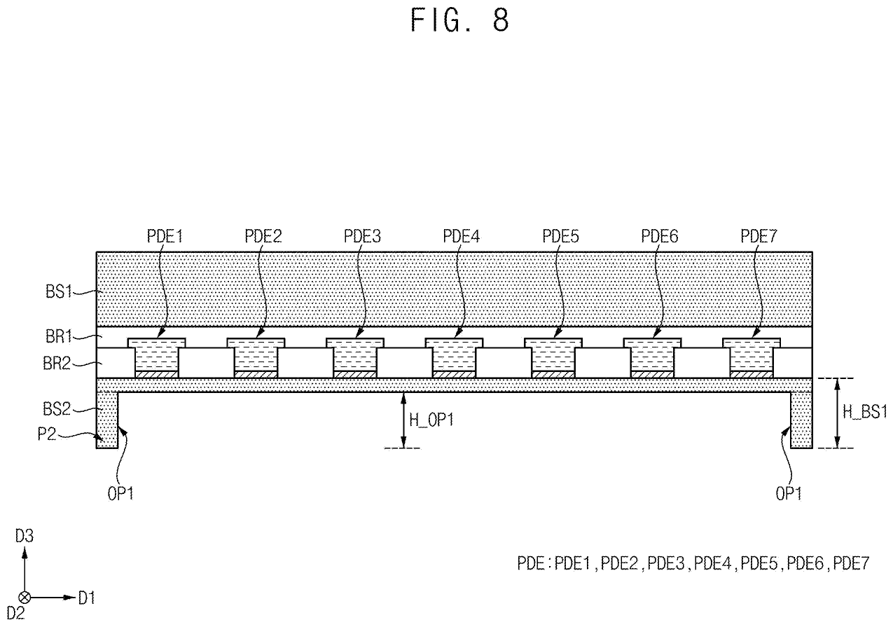

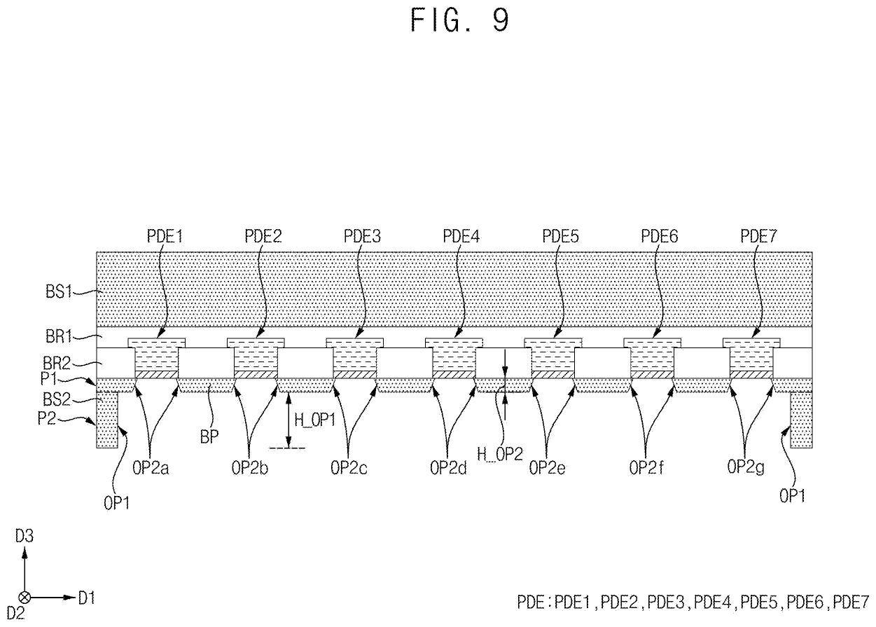

FIG. 7, FIG. 8, and FIG. 9 are cross-sectional views illustrating a method of manufacturing the display device of FIG. 1 according to embodiments of the present disclosure.

Referring to FIG. 7 and in conjunction with FIG. 6, a preliminary lower organic base layer P_BS2, the lower inorganic barrier layer BR2, the pad electrodes PDE, the upper inorganic barrier layer BR1, and the upper organic base layer BS1 may be sequentially formed (e.g., in the third direction D3). In this embodiment, the methods of forming each of the preliminary lower organic base layer P_BS2, the lower inorganic barrier layer BR2, the pad electrodes PDE, the upper inorganic barrier layer BR1, and the upper organic base layer BS1 is not limited, and various known methods may be used.

The circuit layer CIR and the light emitting element layer ELL may be sequentially formed on the upper organic base layer BS1 (e.g., in the third direction D3). In FIG. 7, FIG. 8, and FIG. 9, for convenience of description and not limitation, the circuit layer CIR and the light emitting element layer ELL disposed on the upper organic base layer BS1 is omitted.

Referring to FIG. 8, the second portion P2 defining the pad opening OP1 and a remaining portion disposed on the second portion P2 may be formed by removing a portion of the preliminary lower organic base layer P_BS2 (refer to FIG. 7). For example, the remaining portion may be disposed above the second portion P2 and may cover an entirety of the lower surfaces of the pad electrodes PDE and the lower inorganic barrier layer BR2.

In an embodiment, the portion of the preliminary lower organic base layer P_BS2 may be removed by laser beam. For example, in an embodiment a first laser beam may be irradiated in a direction toward a lower surface of the preliminary lower organic base layer P_BS2 (e.g., the third direction D3) to remove the portion of the preliminary lower organic base layer P_BS2.

In an embodiment, the first laser beam may have relatively low wavelength. For example, in an embodiment a wavelength of the first laser beam may be in a range of about 100 nanometer to about 450 nanometer. Accordingly a process time for a process of removing the portion of the preliminary lower organic base layer P_BS2 using the first laser beam may be relatively short.

In this embodiment, as a thickness H_OP1 of the pad opening OP1 increases (that is, as a thickness of the remaining portion decreases), transmittance of the first laser beam with respect to the remaining portion may increase. In this case, when the transmittance of the first laser beam with respect to the remaining portion is relatively high, the first laser beam may pass through the remaining portion and may be irradiated to the upper organic base layer BS1. Accordingly, the upper organic base layer BS1 may be damaged by the first laser beam.

To prevent this, the remaining portion may have a thickness H_OP2 such that transmittance of the first laser beam with respect to the remaining portion is about 15% or less. For example, in an embodiment in which the wavelength of the first laser beam is about 193 nanometers, the thickness H_OP2 of the remaining portion may be greater than about 0.1 micrometers. In an embodiment in which the wavelength of the first laser beam is about 355 nanometers, the thickness H_OP2 of the remaining portion may be greater than about 1 micrometer. For example, the pad opening OP1 formed by removing the portion of the preliminary lower organic base layer P_BS2 may not expose the lower inorganic barrier layer BR2 and the pad electrodes PDF. Accordingly, the upper organic base layer BS1 may not be damaged by the first laser beam.

Referring to FIG. 9, the first portion P1 defining the contact openings OP2 may be formed by removing a portion of the remaining portion exposed by the pad opening OP1.

In an embodiment, the portion of the remaining portion may be removed by a second laser beam. For example, the second laser beam may be irradiated in a direction toward a lower surface of the portion of the remaining portion (e.g., the third direction D3).

The second laser beam may include various laser beams. For example, in an embodiment the second laser beam may include Gaussian laser beam, homogenizing laser beam, multi-laser beam, etc. However, embodiments of the present disclosure are not necessarily limited thereto.

In an embodiment in which the second laser beam is multi laser beam, the multi-laser beam may include a plurality of sub-laser beams arranged in the first direction D1. In this embodiment, a width of a laser beam array defined as a set of the sub laser beams in the first direction D1 may be substantially the same as a width of lower surface of each of the pad electrodes PDE in the first direction D1.

In an embodiment in which the second laser beam is a homogenizing laser beam, a width of the homogenizing laser beam in the first direction D1 may be substantially the same as the width of lower surface of each of the pad electrodes PDE in the first direction D1.

The portion of the remaining portion removed by the second laser beam may overlap the pad electrodes PDE (e.g., in the third direction D3). For example, the contact openings OP2 may expose the lower surface of the pad electrodes PDE. In this embodiment, since the pad. electrodes PDE are disposed to be spaced apart from each other (e.g., in the first direction D1), the contact openings OP2 may he spaced apart from each other. In addition, the protrusion portion BP may be defined between two adjacent contact openings OP2 among the contact openings OP2.

The foregoing is illustrative of embodiments of the present disclosure and is not to be construed as limiting thereof. Although a few embodiments have been described, those skilled in the art will readily appreciate that many modifications are possible in the embodiments without materially departing from the novel teachings and advantages of the present disclosure. Accordingly, all such modifications are intended to be included within the scope of the present disclosure. Therefore, it is to be understood that the foregoing is illustrative of various embodiments and is not to be construed as necessarily limited to the specific embodiments disclosed, and that modifications to the disclosed embodiments, as well as other embodiments, are intended to be included within the scope of the present disclosure.

What is claimed is:

1. A display device comprising:
a lower inorganic barrier layer;
pad electrodes disposed on the lower inorganic barrier layer and penetrating the lower inorganic barrier layer, wherein the pad electrodes are spaced apart from each other;
an upper inorganic barrier layer disposed on the lower inorganic barrier layer and covering the pad electrodes;
an upper organic base layer disposed on the upper inorganic barrier layer;
a circuit layer disposed on the upper organic base layer;
a light emitting element layer disposed on the circuit layer; and
a lower organic base layer disposed under the lower inorganic barrier layer, the lower organic base layer comprising a first portion defining contact openings respectively exposing the pad electrodes penetrating the lower inorganic barrier layer, and a second portion disposed under the first portion, the second portion defining a pad opening exposing the contact openings.

2. The display device of claim wherein the contact openings are disposed in a pad opening area comprising an area surrounded by an outer edge of the pad opening in a plan view.

3. The display device of claim 2, wherein the pad electrodes are disposed in the pad opening area in the plan view.

4. The display device of claim 1, wherein the contact openings are spaced apart from each other.

5. The display device of claim 4, wherein the first portion of the lower organic base layer comprises protrusion portions disposed between adjacent contact openings of the contact openings.

6. The display device of claim 5, wherein a thickness of each of the protrusion portions is in a range of about 0.1 micrometer to about 2 micrometer in a cross sectional view.

7. The display device of claim 1, wherein a thickness of each of the contact openings is less than a thickness of the pad opening in a cross sectional view.

8. The display device of claim 1, wherein:
the light emitting element layer includes light emitting elements; and
the pad opening is disposed in a display area that has the light emitting elements disposed therein in a plan view.

9. The display device of claim 1, wherein each of the pad electrodes comprises:
a first electrode layer disposed on the lower inorganic barrier layer; and
a second electrode layer disposed under the first electrode layer, wherein an electric conductivity of the second electrode layer is less than an electric conductivity of the first electrode layer.

10. The display device of claim 9, further comprising:
a driving part disposed under the lower organic base layer, the driving part is electrically connected to each of the pad electrodes exposed by the contact openings,
wherein the driving part is electrically connected to the second electrode layer.

11. A method of manufacturing a display device, comprising:
forming a preliminary lower organic base layer;
forming a lower inorganic barrier layer on the preliminary lower organic base layer;
forming pad electrodes penetrating the lower inorganic barrier layer;
forming an upper inorganic barrier layer on the lower inorganic barrier layer to cover the pad electrodes;
forming an upper organic base layer on the upper inorganic barrier layer; and
forming a lower organic base layer by irradiating a laser beam in a direction towards a lower surface of the preliminary lower organic base layer, wherein the lower organic base layer comprises a first portion defining contact openings exposing the pad electrodes penetrating the lower inorganic barrier layer, and a second portion disposed under the first portion, the second portion defining a pad opening exposing the contact openings.

12. The method of claim 11, wherein the forming of the lower organic base layer comprises:
forming the second portion defining the pad opening and a remaining portion disposed on the second portion by irradiating a first laser beam to remove a portion of the preliminary lower organic base layer; and
forming the first portion defining the contact openings by irradiating a second laser beam to remove a portion of the remaining portion exposed by the pad opening.

13. The method of claim 12, wherein a transmittance of the first laser beam with respect to the remaining portion is about 15% or less.

14. The method of claim 11, wherein the contact openings are spaced apart from each other.

15. The method of claim 11, further comprising:
forming a light emitting element layer above the upper organic base layer, the light emitting element layer including light emitting elements,
wherein the pad opening is disposed in a display area having the fight emitting elements disposed therein.

16. The method of claim 11, wherein the first portion of the lower organic base layer comprises protrusion portions disposed between adjacent contact openings of the contact openings.

17. The method of claim 16, wherein a thickness of each of the protrusion portions is in a range of about 0.1 micrometer to about 2 micrometer in a cross sectional view.

18. The method of claim 11, wherein a thickness of each of the contact openings is less than a thickness of the pad opening in a cross sectional view.

19. The method of claim 11, wherein each of the pad electrodes comprises:
a first electrode layer disposed on the lower inorganic barrier layer; and
a second electrode layer disposed under the first electrode layer, wherein an electric conductivity of the second electrode layer is less than an electric conductivity of the first electrode layer.

20. The method of claim 19, further comprising:
forming a driving part under the lower organic base layer, the driving part is electrically connected to each of the pad electrodes exposed by the contact openings,
wherein the driving part is electrically connected to the second electrode layer.
